(19) United States
(12) Patent Application Publication
(10) Pub. No.: US 2025/0226829 A1
(43) Pub. Date: Jul. 10, 2025

(54) CLOCK RECOVERY DEVICE AND DISPLAY DRIVING DEVICE INCLUDING THE SAME

(71) Applicant: LX SEMICON CO., LTD., Daejeon (KR)

(72) Inventors: Jong Suk LEE, Daejeon (KR); Young Bok KIM, Daejeon (KR); Seok Jae OH, Daejeon (KR)

(73) Assignee: LX SEMICON CO., LTD., Daejeon (KR)

(21) Appl. No.: 19/012,293

(22) Filed: Jan. 7, 2025

(30) Foreign Application Priority Data
Jan. 8, 2024 (KR) 10-2024-0003189
Sep. 5, 2024 (KR) 10-2024-0120650

(51) Int. Cl. H03L 7/08; G06F 1/08; G09G 5/00; H04L 7/033

(52) U.S. Cl. CPC H03L 7/0807; G06F 1/08; G09G 5/008; H04L 7/0337; G09G 2310/08

(57) ABSTRACT

A clock recovery device may include a clock generator configured to generate a master clock signal from embedded transmission data, a delay line for generating multi-level clock signals by delaying the master clock signal by a preset reference delay time unit based on an input frequency, a delay controller configured to receive two clock signals delayed by a reference delay time unit among the multi-level clock signals and detect delay time, output a selection signal based on the delay time and the reference delay time, correct the delay time of the master clock signal to the reference delay time based on the selection signal, and output the master clock signal corrected to the reference delay time to the delay line, and a data recovery module configured to recover the multi-level clock signal corrected to the reference delay time through the delay line.

### CROSS-REFERENCE TO RELATED APPLICATIONS

This application claims the priorities of Republic of Korea Patent Application Nos. 10-2024-0003189 filed on Jan. 8, 2024 and 10-2024-0120650 filed on Sep. 5, 2024, which are hereby incorporated by reference in their entirety.

### BACKGROUND

### Field of the Disclosure

The present disclosure relates to a clock recovery device and a display driving device including the same, and more specifically, to a clock recovery device that changes the delay time of a clock signal to the same, and a display driving device including the same.

### Description of the Background

The display device includes a panel that displays an image through a pixel matrix, a gate driver that drives gate lines of the panel, a data driver that supplies data signals to data lines of the panel, a timing controller that controls the gate driver and the data driver, etc. The data driver includes a plurality of data driving ICs (Integrated Circuits) that divide and drive the data lines.

The timing controller serializes parallel data and transmits it to a plurality of data driving ICs, and each of the plurality of data driving ICs may recover clock and data information from the transmission signal and use it.

A clock recovery unit applied to a receiving unit of a conventional display device generates a clock having a delay time equal to an embedded clock frequency.

The delay times inside the voltage-controlled delay line in the clock recovery section have constant values because the input/output capacitances are the same, but since the capacitor capacity or length of the line providing the master clock signal is different from the capacitor capacity or length inside the voltage-controlled delay line, the first delay time has an error with the second delay time.

Due to the error that occurs as described above, a certain section of the setup or hold margin is damaged during data recovery, which reduces the range of application.

### SUMMARY

Accordingly, the present disclosure is directed to a clock recovery device and a display driving device including the same that substantially obviate one or more of problems due to limitations and disadvantages described above.

More specifically, the present disclosure is to provide a clock recovery device and a display driving device including the same for preventing an error in delay time from occurring according to input/output capacitance.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a clock recovery device may include a clock generator configured to generate a master clock signal from embedded transmission data, a delay line for generating multi-level clock signals by delaying the master clock signal by a preset reference delay time unit based on an input frequency, a delay controller configured to receive two clock signals delayed by a reference delay time unit among the multi-level clock signals and detect delay time, output a selection signal based on the delay time and the reference delay time, correct the delay time of the master clock signal to the reference delay time based on the selection signal, and output the master clock signal corrected to the reference delay time to the delay line, and a data recovery module configured to recover the multi-level clock signal corrected to the reference delay time through the delay line.

The delay controller may increase the delay time by reducing a rising time of the clock signal through an inverter of a determined size when an input frequency is a low frequency.

The delay controller may include a first inverter of a large size and a second inverter of a small size, and the inverter of the determined size may be the first inverter.

The delay controller may reduce a delay time by increasing a rising time of the clock signal through an inverter of a determined size when an input frequency is a high frequency.

The delay controller may include a first inverter of a large size and a second inverter of a small size, and the inverter of the determined size may be the second inverter.

The delay line is composed of a plurality of inverters, and may generate the multi-level clock signal by passing through the plurality of inverters.

In addition, to solve the above problem, a display driving device recovering a clock signal and data from an input signal and driving a display panel using the recovered clock signal and data may include a clock recovery device including: a clock generator configured to generate a master clock signal from embedded transmission data; a delay line for generating multi-level clock signals by delaying the master clock signal by a preset reference delay time unit based on an input frequency; a delay controller configured to receive two clock signals delayed by a reference delay time unit among the multi-level clock signals and detect delay time, output a selection signal based on the delay time and the reference delay time, correct the delay time of the master clock signal to the reference delay time based on the selection signal, and output the master clock signal corrected to the reference delay time to the delay line; and a data recovery module configured to recover the multi-level clock signal corrected to the reference delay time through the delay line.

The delay control unit may compare the delay time with the reference delay time, and output the selection signal including ‘1’or ‘0’ based on the comparison result.

The delay control unit may determine a size of an inverter to output the master clock signal based on the selection signal.

In another aspect of the present disclosure, a clock recovery method may include generating a master clock signal from embedded transmission data, generating multi-level clock signals by delaying the master clock signal by a preset reference delay time unit based on an input frequency, receiving two clock signals delayed by a reference delay time unit among the multi-level clock signals, detecting the delay time, comparing the delay time with the reference delay time, outputting a selection signal based on the comparison result, and determining a size of an inverter outputting the master clock signal based on the selection signal, and recovering the multi-level clock signals whose delay time is corrected to the reference delay time by passing through an inverter of the determined size.

In the step of determining the size of the inverter, when the input frequency is a low frequency, the delay time may be increased by reduced a rising time of the clock signal through the inverter of the determined size.

In the step of determining the size of the inverter, the inverter may include a first inverter of a big size and a second inverter of a small size, and the inverter of the determined size may be the first inverter.

In the step of determining the size of the inverter, when the input frequency is a high frequency, the delay time may be reduced by increasing a rising time of the clock signal through the inverter of the determined size.

In the step of determining the size of the inverter, the inverter may include a first inverter of a big size and a second inverter of a small size, and the inverter of the determined size may be the second inverter.

The step of generating the multi-level clock signals may generate the multi-level clock signals by passing through a plurality of inverters.

The aspect may increase the frequency range in which the clock recovery device may operate by securing a setup or hold margin during data recovery.

In addition, the aspect may increase the operating range of the clock recovery device, thereby expanding the application range.

In addition, the aspect may improve the yield loss of the device.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a block diagram of a display driving device and a display device including the same according to an aspect of the present disclosure.

FIG. 2 is a configuration diagram illustrating a clock recovery device equipped in a display driving device according to an aspect of the present disclosure.

FIG. 3 is a circuit diagram illustrating the structure of a voltage-controlled delay line of a clock recovery device according to an aspect of the present disclosure.

FIG. 4 is a circuit diagram illustrating the structure of a delay control unit of a clock recovery device according to an aspect of the present disclosure.

FIG. 5 is a timing diagram illustrating a conventional delay time when the input frequency is a low frequency.

FIG. 6 is a timing diagram illustrating a delay time according to an aspect of the present disclosure when the input frequency is a low frequency.

FIG. 7 is a timing diagram illustrating a conventional delay time when the input frequency is high frequency.

FIG. 8 is a timing diagram illustrating a delay time according to an aspect of the present disclosure when the input frequency is high frequency.

FIG. 9 is a graph illustrating a first delay range according to an increase in data rate by a big size inverter.

FIG. 10 is a graph illustrating a first delay range according to an increase in data rate by a small size inverter.

FIG. 11 is a flowchart illustrating a clock recovery method according to an aspect of the present disclosure.

FIG. 12 is a flowchart illustrating a detailed process of determining an inverter size according to an aspect of the present disclosure.

### DETAILED DESCRIPTION

Hereinafter, aspects will be described in detail with reference to the attached drawings. The aspects may have various modifications and may take various forms, and thus specific aspects will be illustrated in the drawings and described in detail in the text. However, this is not intended to limit the aspects to a specific disclosed form, and it should be understood that it includes all modifications, equivalents, or substitutes included in the spirit and technical scope of the aspects.

Terms such as “first” and “second” may be used to describe various components, but the components should not be limited by the terms. The terms are used for the purpose of distinguishing one component from another. In addition, terms specifically defined in consideration of the configuration and operation of the aspects are only for describing the aspects, and do not limit the scope of the aspects.

In the description of the aspect, when it is described as being formed “on or under” each element, “on or under” includes both the two elements being directly in contact with each other or one or more other elements being positioned indirectly between the two elements. In addition, when expressed as “on or under,” it may include the meaning of not only the upward direction but also the downward direction based on one element.

In addition, relational terms such as “upper/upper/top” and “lower/lower/below” used below may be used to distinguish one entity or element from another entity or element, without necessarily requiring or implying any physical or logical relationship or order between such entities or elements.

The receiving unit device according to the aspect may be configured to include a serial-to-parallel converter that receives transmission data (clock embedded data: CED) (hereinafter, collectively referred to as “transmission data (CED) ”) in the form of a clock signal transmitted from a timing control unit through a serial signal line, converts it into parallel data, and then transmits a recovered data signal (recovered data) to a display panel, and a clock recovery device according to the aspect that extracts an embedded clock signal from the transmission data (CED) in which the clock signal is embedded between data signals and transmits a sampling clock signal used for recovering the data signal to the serial-to-parallel converter and outputs a recovered clock signal (recovered clock) for data output.

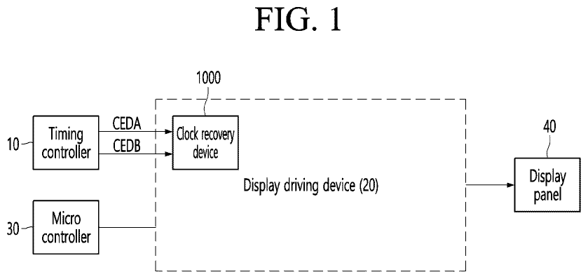

FIG. 1 is a block diagram of a display driving device according to the aspect and a display device including the same.

Referring to FIG. 1, the display device according to the aspect may include a timing controller 10, a display driving device 20, a microcontroller 30, and a display panel 40.

The timing controller 10 receives image data and timing signals from a host system (not shown), performs image processing such as image quality compensation on the image data, and provides a differential input signal (CEDA, CEDB) with a clock embedded in the data (image and control data) to the display driving device.

The display driving device 20 may recover the clock signal and data from the input signal (CEDA, CEDB) and drive the display panel 40 using the recovered clock signal and data. In addition, the display driving device 20 may detect a touch of the display panel 40 using the recovered clock signal.

The display driving device 20 may be equipped with a clock recovery device 1000 for recovering the clock.

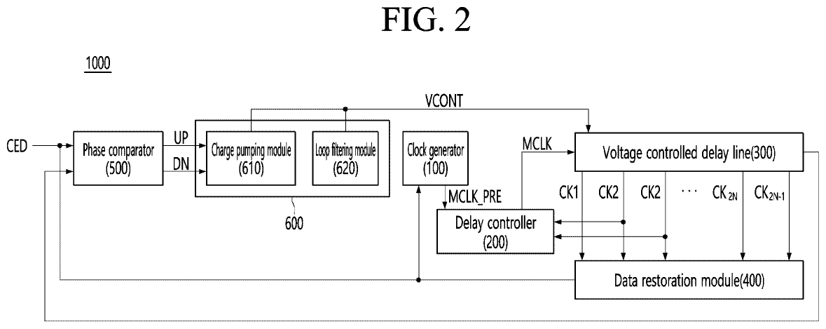

FIG. 2 is a configuration diagram illustrating a clock recovery device according to an aspect of the present disclosure.

Referring to FIG. 2, the clock recovery device 1000 according to the aspect may include a clock generator 100, a delay control unit 200, a voltage controlled delay line (VCDL, 300), a data recovery unit 400, a phase comparison unit 500, and a low-pass filter 600.

The clock generator 100 may receive transmission data (Clock Embedded Data: CED) in which a clock signal transmitted from a transmitter is embedded between data signals. The clock generator 100 may receive multi-level clock signals (CK1, CK2 . . . CK2N+1), which are delay clock signals output from a voltage controlled delay line 300, as inputs.

The clock generator 100 may generate a master clock signal (MCLK_PRE) by transmission data (CED) configured in the form of a clock signal input during a clock training period before the multi-level clock signals are generated. At this time, the number of multi-level clock signals must be at least greater than or equal to 2N+1, where N is a natural number representing the number of data bits existing between clock bits.

The delay control unit 200 according to the aspect may receive the master clock signal (MCLK_PRE). The delay control unit 200 may correct the delay time by using the multi-level clock signals output from the voltage-controlled delay line 300 and output the master clock signal (MCLK) whose delay time is corrected to the voltage-controlled delay line 300. The delay control unit 200 according to the aspect will be described in detail later.

The voltage-controlled delay line 300 may generate a multi-level clock signal by delaying the master clock signal (MCLK_PRE) by a preset reference delay time unit based on the input frequency. In addition, the voltage-controlled delay line 300 may generate a multi-level clock signal based on the master clock signal (MCLK) whose delay time is corrected.

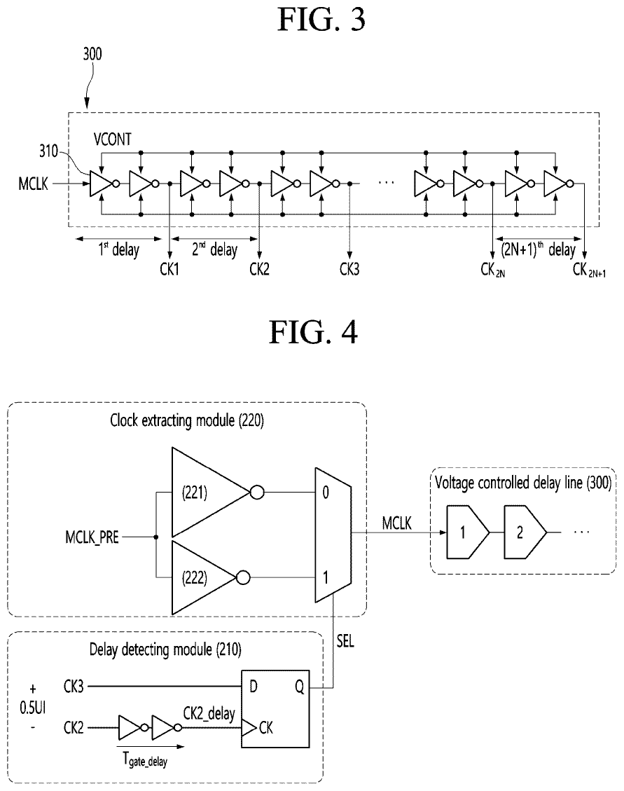

FIG. 3 is a circuit diagram illustrating the structure of a voltage-controlled delay line of a clock recovery device according to an aspect of the present disclosure.

As shown in FIG. 3, the voltage-controlled delay line 300 may be configured based only on a delay-locked loop (DLL) equipped with a plurality of delay means capable of receiving, delaying, and outputting a master clock signal (MCLK).

A plurality of inverters 310 may be used as the delay means. A plurality of inverters 310 uses two inverter pairs as one delay unit, and generate and output a delayed clock signal (CK1, CK2, CK3, . . . CK2N+1) while passing through the inverter pairs composed of two inverters.

In the above, the voltage-controlled delay line was described as a delay line, but it may also be configured as a current-controlled delay line (CCDL).

Returning to FIG. 2, the data recovery unit 400 may recover the remaining portion except for the edge of the clock signal output from the voltage-controlled delay line 300 and inserted between data.

The phase difference comparison unit 500 has as inputs any two signals among the multi-level clock signals delayed in the voltage-controlled delay line 300 based on the delay- locked loop along with the input clock signal of the delay-locked loop equipped with the delay means, and may generate an up/down signal (UP/DN) as a delay amount control signal by the time difference between the two signals.

When the lock signal becomes a logic high state and the delay-locked loop is locked, the phase difference comparison unit 500 has as inputs the master clock signal (MCLK) output from the clock generator 100 and any two clock signals among the delay clock signals (CK1, CK2, CK3, . . . , CK2N+1) output from the voltage-controlled delay line 300 whose time difference is the same as the cycle in which the clock bit is inserted. It may be configured to generate an up/down signal according to the time difference between these two input clock signals.

The low-pass filter 600 may remove or reduce the high-frequency component of the up/down signal (UP/DN) generated by the time difference of the two clock signals in the phase difference comparison unit 500 to output a voltage signal (VCOUNT). The low-pass filter 600 may be configured by a combination of a charge pump unit 610 and a loop filter unit 620.

Meanwhile, since the capacitor capacity or the length of the line providing the master clock signal in FIG. 3 is different from the capacitor capacity or length inside the voltage control delay line, the first delay time may be different from the second delay time.

In the aspect, the first delay time may be changed using a clock recovery device.

FIG. 4 is a circuit diagram illustrating the structure of the delay control unit of the clock recovery device according to the aspect.

Referring to FIG. 4, the delay control unit 200 according to the aspect may include a delay detector 210 and a clock extractor 220.

The delay detector 210 may receive two clock signals (CK2, CK3) delayed by a reference delay time unit among multi-level clock signals and detect a delay time (CK2_delay) for the clock signal of CK2.

The delay detector 210 may compare the delay time (CK2_delay) with the reference delay time and output a selection signal based on the comparison result. Here, the reference delay time may be a predetermined time. For example, the reference delay time may be 0.5 UI, but the reference delay time may vary.

The clock extractor 220 may determine or change the inverter size that outputs the master clock signal based on the selection signal. Here, the selection signal may be ‘1’ or ‘0’. The clock extractor 220 may include a first inverter 221 of a big size and a second inverter 222 of a small size, but the number is not limited.

For example, when the input frequency is a low frequency, the first delay time may be increased by using the first inverter 221 of a big size. On the other hand, when the input frequency is a high frequency, the first delay time may be decreased by using the second inverter 222 of a small size.

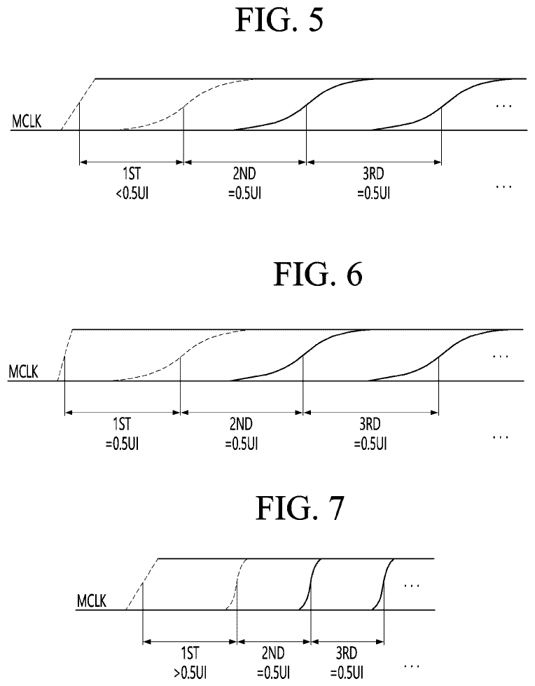

FIG. 5 is a timing diagram illustrating a conventional delay time when the input frequency is a low frequency.

As shown in FIG. 5, when the input frequency is a low frequency, the first delay time may be smaller than the second delay time or the third delay time, which is 0.5 UI.

FIG. 6 is a timing diagram illustrating a delay time according to an aspect of the present disclosure when the input frequency is a low frequency.

As shown in FIG. 6, when the input frequency is a low frequency, if a big-sized first inverter is selected by the delay control unit according to the aspect, the rising time of the first delay time becomes shorter, and accordingly, the first delay time may have 0.5 UI, which is the same as the second delay time or the third delay time.

FIG. 7 is a timing diagram illustrating a conventional delay time when the input frequency is a high frequency.

As shown in FIG. 7, when the input frequency is a high frequency, the first delay time may be greater than 0.5 UI, which is the second delay time or the third delay time.

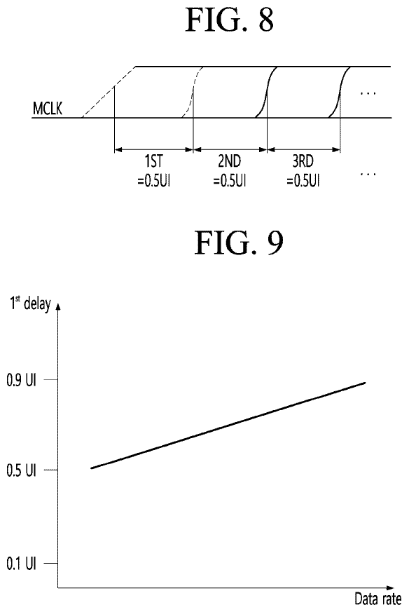

FIG. 8 is a timing diagram illustrating a delay time according to an aspect of the present disclosure when the input frequency is a high frequency.

As shown in FIG. 8, when the input frequency is high frequency, if the second inverter of the small size is selected by the delay control unit according to the aspect, the rising time of the first delay time increases, and accordingly, the first delay time may have 0.5 UI, which is the same as the second delay time or the third delay time.

FIG. 9 is a graph illustrating the first delay range according to the increase in data rate by the big size inverter.

As shown in FIG. 9, the first inverter of the big size may have a specification in which the first delay time increases in the range of 0.5 UI to 0.9 UI according to the increase in data transmission speed (data rate). The above change range may be changed by the user according to the preset reference delay time.

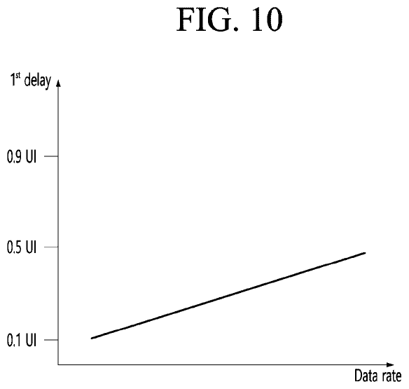

FIG. 10 is a graph illustrating the first delay range according to the increase in data rate by the small size inverter.

As shown in FIG. 10, the second inverter of the small size may have a specification in which the first delay time increases in the range of 0.1 UI to 0.5 UI as the data transmission speed (Data rate) increases. The above change range may be changed by the user according to the preset reference delay time.

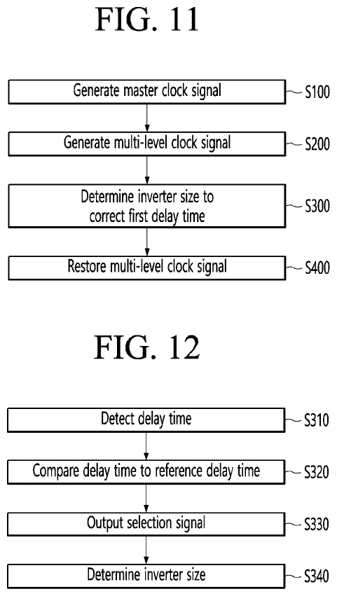

FIG. 11 is a flowchart illustrating a clock recovery method according to an aspect of the present disclosure.

Referring to FIG. 11, the clock recovery method according to the aspect may perform a step of generating a master clock signal (S100), a step of generating a multi-level clock signal (S200), a step of determining an inverter size for compensating the first delay time (S300), and a step of recovering a multi-level clock signal (S400).

The clock recovery method according to the aspect may be performed in a clock recovery device according to the aspect.

The clock generation unit may generate a master clock signal from embedded transmission data (S100). In more detail, the clock generation unit may receive transmission data (CED) in which a clock signal transmitted from the transmission unit is embedded between data signals. The clock generation unit may receive multi-level clock signals (CK1, CK2 . . . CK2N+1) output from the voltage-controlled delay line as input. The clock generation unit may generate a master clock signal (MCLK) by transmission data (CED) configured in the form of a clock signal input during the clock training period before the multi-level clock signals are generated.

The voltage-controlled delay line may generate a multi-level clock signal by delaying the master clock signal by a preset standard delay time unit based on the input frequency (S200).

In more detail, the voltage-controlled delay line may be configured based only on a delay-locked loop (DLL) equipped with a plurality of delay means capable of receiving, delaying, and outputting a master clock signal. A plurality of inverters may be used as the delay means. Multiple inverters use two inverter pairs as one delay unit, and generate and output a delayed clock signal (CK1, CK2, CK3, . . . CK2N+1) while passing through the inverter pairs composed of two inverters.

The delay control unit may determine the inverter size for correcting the first delay time (S300). The delay control unit may output a master clock signal whose delay time has been corrected by passing through the inverter.

FIG. 12 is a flowchart illustrating a detailed process for determining the inverter size according to an aspect of the present disclosure.

As shown in FIG. 12, the delay control unit may receive two clock signals delayed by a reference delay time unit among the multi-level clock signals and detect the delay time (S310).

The delay control unit may compare the delay time with a preset reference delay time (S320).

The delay detector may compare the delay time with the reference delay time and output a selection signal based on the comparison result (S330). Here, the selection signal may include ‘1’ or ‘0’.

The delay detector may determine or change the inverter size that outputs the master clock signal based on the selection signal (S340).

For example, when the input frequency is low frequency, the first delay time may be increased by using a first inverter of a large size. On the other hand, when the input frequency is high frequency, the first delay time may be decreased by using a second inverter of a small size.

Returning to FIG. 11, the data recovery unit may recover a multi-level clock signal generated based on the corrected master clock signal (S400).

Although the above has been described with reference to the drawings and aspects, it will be understood by those skilled in the art that the aspects of the present disclosure may be variously modified and changed within a scope that does not depart from the technical idea of the present disclosure described in the patent claims. Thus, it is intended that the present disclosure covers the modifications and variations of the aspects provided they come within the scope of the appended claims and their equivalents.

What is claimed is:

1. A clock recovery device comprising:
a clock generator configured to generate a master clock signal from embedded transmission data;
a delay line for generating multi-level clock signals by delaying the master clock signal by a preset reference delay time unit based on the master clock signal;
a delay controller configured to receive two clock signals delayed by a reference delay time unit among the multi-level clock signals and detect delay time, output a selection signal based on the delay time and the reference delay time, correct the delay time of the master clock signal to the reference delay time based on the selection signal, and output the master clock signal corrected to the reference delay time to the delay line; and
a data restoration module configured to restore the multi-level clock signal corrected to the reference delay time through the delay line.

2. The clock recovery device of claim 1, wherein the delay controller is configured to compare the delay time with the reference delay time, and output the selection signal including ‘1’ or ‘0’ based on the comparison result.

3. The clock recovery device of claim 1, wherein the delay controller is configured to determine a size of an inverter to output the master clock signal based on the selection signal.

4. The clock recovery device of claim 3, wherein, when an input frequency is a low frequency, the delay controller is configured to increase the delay time by reducing a rising time of the clock signal through the inverter of the determined size.

5. The clock recovery device of claim 4, wherein the delay controller includes a first inverter and a second inverter smaller in size than the first inverter, and the inverter of the determined size is the first inverter.

6. The clock recovery device of claim 3, wherein, when an input frequency is a high frequency, the delay controller is configured to reduce the delay time by increasing a rising time of the clock signal through the inverter of the determined size.

7. The clock recovery device of claim 6, wherein the delay controller includes a first inverter and a second inverter smaller in size than the first inverter, and the inverter of the determined size is the second inverter.

8. The clock recovery device of claim 3, wherein the delay line is composed of a plurality of inverters, and is configured to generate the multi-level clock signal by passing through the plurality of inverters.

9. A display driving device restoring a clock signal and data from an input signal and driving a display panel using the restored clock signal and data, comprising:
a clock recovery device including:
a clock generator configured to generate a master clock signal from embedded transmission data;
a delay line for generating multi-level clock signals by delaying the master clock signal by a preset reference delay time unit based on the master clock signal;
a delay controller configured to receive two clock signals delayed by a reference delay time unit among the multi-level clock signals and detect delay time, output a selection signal based on the delay time and the reference delay time, correct the delay time of the master clock signal to the reference delay time based on the selection signal, and output the master clock signal corrected to the reference delay time to the delay line; and
a data restoration module configured to restore the multi-level clock signal corrected to the reference delay time through the delay line.

10. The display driving device of claim 9, wherein the delay controller is configured to compare the delay time with the reference delay time, and output the selection signal including ‘1’ or ‘0’ based on the comparison result.

11. The display driving device of claim 10, wherein the delay controller is configured to determine a size of an inverter to output the master clock signal based on the selection signal.

12. The display driving device of claim 11, wherein, when an input frequency is a low frequency, the delay controller is configured to increase the delay time by reducing a rising time of the clock signal through the inverter of the determined size.

13. The display driving device of claim 12, wherein the delay controller includes a first inverter and a second inverter smaller in size than the first inverter, and the inverter of the determined size is the first inverter.

14. The display driving device of claim 11, wherein, when an input frequency is a high frequency, the delay controller is configured to reduce the delay time by increasing a rising time of the clock signal through the inverter of the determined size.

15. The display driving device of claim 14, wherein the delay controller includes a first inverter and a second inverter smaller in size than the first inverter, and the inverter of the determined size is the second inverter.

16. The display driving device of claim 11, wherein the delay line is composed of a plurality of inverters, and is configured to generate the multi-level clock signal by passing through the plurality of inverters.

17. A clock restoration method comprising:
generating a master clock signal;
generating a multi-level clock signal by delaying the master clock signal by a preset reference delay time unit based on the master clock signal;
receiving two clock signals delayed by a reference delay time unit among the multi-level clock signals, detecting the delay time, outputting a selection signal based on the delay time and the reference delay time, correcting the delay time of the master clock signal to the reference delay time based on the selection signal, and outputting the master clock signal corrected to the reference delay time to a delay line; and
restoring the multi-level clock signal corrected to the reference delay time through the delay line.

18. The clock restoration method of claim 17, further comprising:
comparing the delay time with the reference delay time; and
outputting the selection signal including ‘1’ or ‘0’ based on the comparison result.

19. The clock restoration method of claim 17, further comprising determining a size of an inverter outputting the master clock signal based on the selection signal.

20. The clock restoration method of claim 19, further comprising increasing the delay time by reducing a rising time of the clock signal through the inverter of the determined size, when an input frequency is a low frequency.
